(19) United States
(12) Patent Application Publication
(10) Pub. No.: US 2013/0337394 A1
(43) Pub. Date: Dec. 19, 2013

(54) HEAT TREATMENT APPARATUS

(71) Applicant: Tokyo Electron Limited, Tokyo (JP)

(72) Inventors: Shinji ASARI, Oshu-shi (JP); Hidekazu SATO, Oshu-shi (JP); Hideki TAKAHASHI, Oshu-shi (JP)

(21) Appl. No.: 13/917,759

(22) Filed: Jun. 14, 2013

(30) Foreign Application Priority Data
Jun. 18, 2012 (JP) 2012-136837

(51) Int. Cl. F27D 7/06; F27D 5/00; F27D 11/02; H01L 21/67

(52) U.S. Cl. CPC F27D 7/06; H01L 21/67098; F27D 5/0037; F27D 11/02
USPC 432/198; 432/247; 432/253

(57) ABSTRACT

According to one aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a gas supply system configured to supply the inert gas, wherein the gas supply system includes a gas supply header portion located in a lower end of the processing chamber to allow the inert gas to flow along a circumferential direction of the lower end; and a gas introduction portion in communication with the gas supply header portion to introduce the inert gas into the processing chamber.

### CROSS-REFERENCE TO RELATED APPLICATION

This application claims the benefit of Japanese Patent Application No. 2012-136837, filed on Jun. 18, 2012, in the Japan Patent Office, the disclosure of which is incorporated herein in its entirety by reference.

### TECHNICAL FIELD

The present disclosure relates to a heat treatment apparatus configured to perform heat treatment such as vitrification of photoresist applied to an object to be treated such as a semiconductor wafer.

Generally, in order to manufacture a semiconductor integrated circuit, a variety of treatments, such as film formation treatments, etching treatments using a photolithography technique, oxidation treatments, diffusion treatments, modification treatments, and the like are performed on a semiconductor wafer such as a silicon substrate. In the photolithography technique, photoresist is applied to a semiconductor wafer such as a silicon substrate and then vitrified. Thereafter, a mask pattern is transferred to the photoresist through exposure by irradiating the photoresist with ultraviolet rays or the like through a photomask. Finally, a photoresist pattern is formed by a development process.

The photoresist includes, for example, a mixture liquid of a photosensitizing agent, resin, solvent, and the like. After the photoresist is applied to the semiconductor wafer, the semiconductor wafer is subjected to a pre-bake or post-bake process, whereby moisture or volatile components are evaporated from the photoresist to vitrify the thin film of the photoresist as described above.

Here, when the vitrification is performed, particularly through the post-bake process, a vertical type heat treatment apparatus is preferred since the vitrification can be performed on plural sheets of wafers at a time.

In such a heat treatment apparatus, plural sheets of semiconductor wafers, in which a photoresist has been applied and the pre-bake process has been completely performed, are supported in a vertical type cylindrical processing chamber in a multistage manner, and the semiconductor wafers are heated by a heater while a large amount of an inert gas such as an N₂ gas is supplied into the processing chamber. Then, the moisture or volatile components generated from the photoresist by heating are discharged together with the N₂ gas, such that the photoresist is vitrified. For example, the N₂ gas is introduced from the bottom of the processing chamber and is allowed to flow upward in the processing chamber, and the volatile components in the N₂ gas are discharged.

However, since it is difficult to transfer the heat of the heater to a bottom region of the aforementioned processing chamber and there is also a large amount of heat dissipation, the bottom region is likely to become a low temperature region of a cold spot state. In addition, evaporated gas containing photosensitizing agent components as well as pure volatile components may also be generated when the vitrification is performed. Then, the evaporated gas is cooled. When the evaporated gas is brought into contact with the low temperature region at the bottom of the processing chamber, the gas is cooled and powdery or liquid deposition, which is causative of particles, is generated in this region and attached thereto. For example, when polyimide resin is used as the photoresist, tar-like liquid containing carbon is attached to the low temperature region.

### SUMMARY

The present disclosure provides a heat treatment apparatus capable of preventing powdery or liquid deposition from being attached to a bottom of a processing chamber.

According to one aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a gas supply system configured to supply the inert gas, wherein the gas supply system includes a gas supply header portion located in a lower end of the processing chamber to allow the inert gas to flow along a circumferential direction of the lower end; and a gas introduction portion in communication with the gas supply header portion to introduce the inert gas into the processing chamber.

According to another aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a gas supply system configured to supply the inert gas, wherein the gas supply system includes an inert gas heating unit installed to an inert gas channel to heat the inert gas, wherein the inert gas channel allows the inert gas to flow.

According to still another aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a winding channel structure positioned between a lower end of the processing chamber and a heat retention unit configured to retain temperature of a lower end of the holding and supporting unit, thereby defining a winding channel configured to hinder the flow of the inert gas flowing upward and to heat the inert gas.

According to still another aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a lower chamber heating unit installed to the lower end of the processing chamber along the circumferential direction thereof to heat the inert gas introduced into the processing chamber.

According to still another aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a gas supply system configured to supply the inert gas, wherein the gas supply system includes a gas supply header portion located in a lower end of the processing chamber to allow the inert gas to flow along a circumferential direction of the lower end, and a gas introduction portion in communication with the gas supply header portion to introduce the inert gas into the processing chamber; and a winding channel structure positioned between a lower end of the processing chamber and a heat retention unit configured to retain temperature of a lower end of the holding and supporting unit, thereby defining a winding channel configured to hinder the flow of the inert gas flowing upward and to heat the inert gas.

According to still another aspect of the present disclosure, provided is a heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound. The heat treatment apparatus includes a gas supply system configured to supply the inert gas, wherein the gas supply system includes a gas supply header portion located in a lower end of the processing chamber to allow the inert gas to flow along a circumferential direction of the lower end, and a gas introduction portion in communication with the gas supply header portion to introduce the inert gas into the processing chamber; and a lower chamber heating unit located in the lower end of the processing chamber to heat the inert gas introduced into the processing chamber along the circumferential direction of the lower end.

### BRIEF DESCRIPTION OF THE DRAWINGS

The accompanying drawings, which are incorporated in and constitute a part of the specification, illustrate embodiments of the present disclosure and, together with the general description given above and the detailed description of the embodiments given below, serve to explain the principles of the present disclosure.

FIG. 1 is a view showing the configuration of a first embodiment of a heat treatment apparatus according to the present disclosure.

FIG. 2 is a sectional view showing an example of a heat retention unit in the heat treatment apparatus.

FIGS. 3A and 3B are sectional views of a gas supply header portion with a gas introduction portion, and modification of the gas supply header portion, respectively.

FIGS. 4A and 4B are views partially showing modifications of the gas supply header portion.

FIG. 5 is a partial view showing the configuration of a second embodiment of the heat treatment apparatus according to the present disclosure.

FIGS. 6A and 6B are a partial view showing the configuration of a bottom of the processing chamber of a third embodiment of the heat treatment apparatus according to the present disclosure and an enlarged view thereof, respectively.

FIG. 7 is a partial view showing the configuration of a fourth embodiment of the heat treatment apparatus according to the present disclosure.

FIGS. 8A and 8B are partial views showing the configuration of an example of the heat treatment apparatus in which the first and third embodiments are combined, and the first and fourth embodiments are combined, respectively.

### DETAILED DESCRIPTION

Hereinafter, embodiments of a heat treatment apparatus according to the present disclosure will be described with reference to the drawings. In addition, throughout the drawings, like reference numerals are used to designate like elements.

### First Embodiment

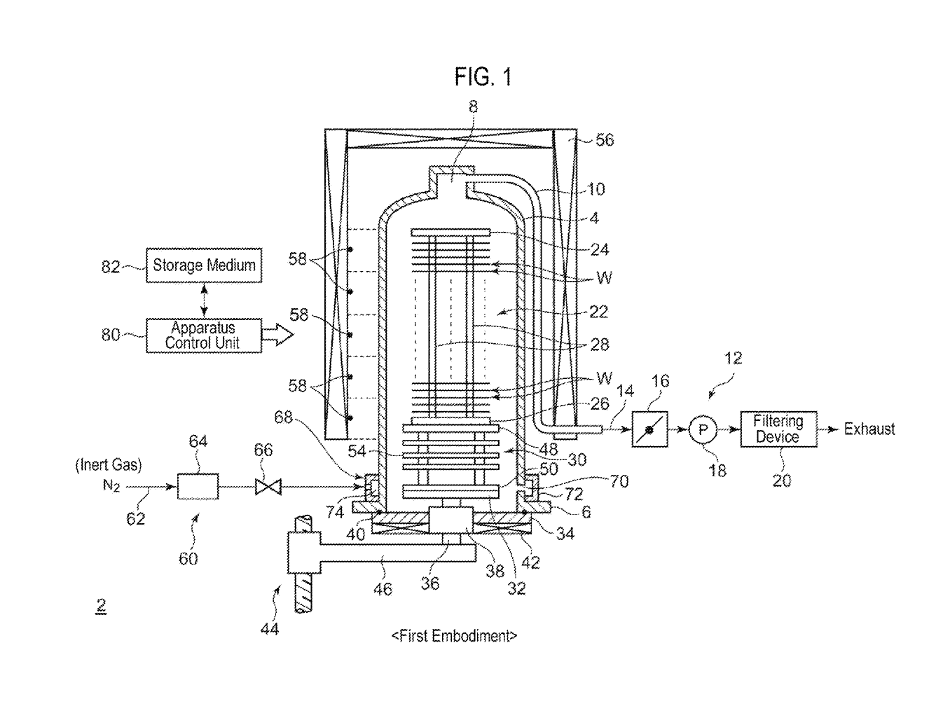

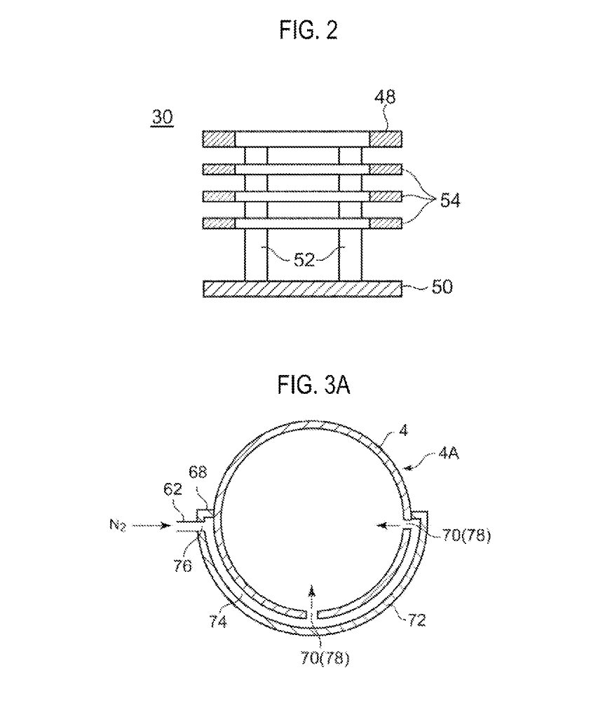

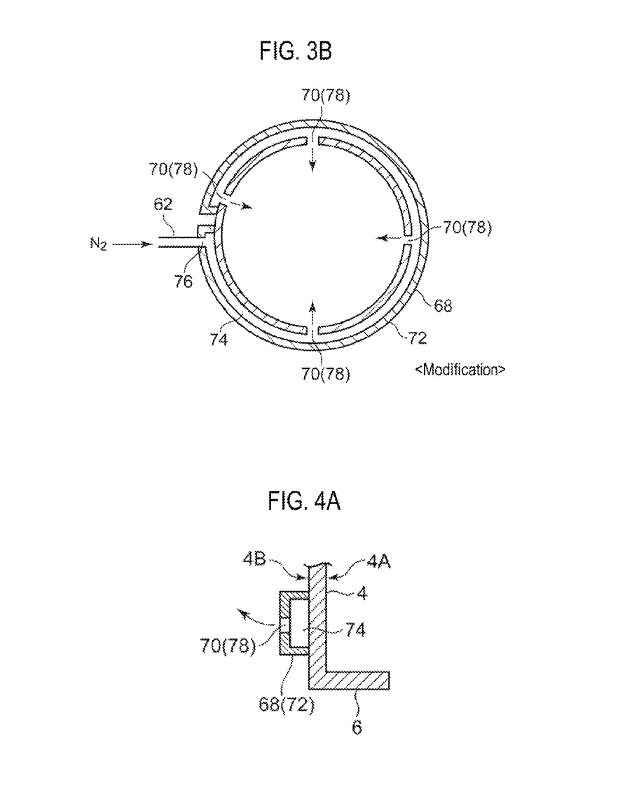

FIG. 1 is a view showing the configuration of a first embodiment of a heat treatment apparatus according to the present disclosure; FIG. 2 is a sectional view showing an example of a heat retention unit in the heat treatment apparatus; and FIGS. 3A and 3B are sectional views of a gas supply header portion with a gas introduction portion, and modification of the gas supply header portion, respectively.

As shown in the figures, a heat treatment apparatus 2 has an elongated batch type processing chamber 4 in the shape of a cylinder having an open lower end. The processing chamber 4 is formed in a cylindrical shape, for example, of quartz having high thermal resistance and with a flange portion 6 formed in the lower end thereof. This processing chamber 4 has an upward protruding exhaust chamber 8 formed in a ceiling portion thereof. An exhaust pipe 10, for example made of quartz, is formed to extend from the exhaust chamber 8, extends downward along an outer wall of the processing chamber 4, and then is bent in the horizontal direction at a lower portion of the processing chamber 4. In addition, an evacuation system 12 is connected to the exhaust pipe 10 to evacuate the atmosphere of the processing chamber 4.

The evacuation system 12 has an exhaust channel 14, for example made of stainless steel, connected to a leading end of the exhaust pipe 10. The exhaust channel 14 is fitted with a pressure adjustment valve 16, a vacuum pump 18, and filtering device 20 which are installed sequentially from the upstream side thereof toward the downstream side. The pressure in the processing chamber 4 can be adjusted by control of the pressure adjustment valve 16. Also, for example, an ejector may be used as the vacuum pump 18 which can be omitted when the process pressure is close to the normal pressure. The filtering device 20 is configured to be capable of removing harmful substance from exhaust gas.

In addition, a wafer boat 22, which is a holding and supporting unit for holding and supporting a plurality of semiconductor wafers W, which are objects to be treated, is configured to be liftably inserted (loaded) into or separated (unloaded) from the processing chamber 4 through the opening of the lower end thereof. The wafer boat 22 is formed, for example, of quartz in its entirety. Specifically, the wafer boat 22 has a ceiling plate 24, a bottom plate 26, and a plurality of pillars, for example, four pillars 28 (only two of which are shown in FIG. 1) displaced between the ceiling plate 24 and the bottom plates 26.

Support grooves (not shown) are formed in each pillar 28 at predetermined pitches, and peripheral portions of wafers W are supported in the support grooves, so that a plurality of wafers W can be held and supported in a multistage manner. In addition, a wafer W is allowed to be loaded into or unloaded from a lateral side of the wafer boat 22. The wafer boat 22 allows, for example, about 50 to 150 sheets of wafers W each having a diameter of 300 mm to be held and supported therein.

The wafer boat 22 is mounted on a table 32 through a heat retention unit 30 of quartz, and the table 32 is installed to an upper end of a rotating shaft 36, which penetrates a lid portion 34 for opening and closing the opening of the lower end of the processing chamber 4. In addition, the portion penetrated by the rotating shaft 36 is fitted, for example, with a magnetic fluid seal 38, thereby air-tightly sealing and rotatably supporting the rotating shaft 36. Further, a sealing member 40 such as an O-ring is installed between a peripheral portion of the lid portion 34 and the flange portion 6 of the processing chamber 4, thereby maintaining sealing properties in the processing chamber 4. Also, a lid portion heater 42 for heating the lid portion 34 is mounted thereto.

The rotating shaft 36 is mounted to a leading end of an arm 46 supported by a lift mechanism 44 such as a boat elevator and is configured to lift up or down the wafer boat 22, the lid portion 34, and the like integrally. In addition, the heat retention unit 30 is formed of quartz in its entirety as described above. As shown in FIG. 2, the heat retention unit 30 has a circular ring-shaped ceiling plate 48, a circular disk-shaped bottom plate 50, and a plurality of pillars, for example, four pillars 52 (only two of which are shown in FIG. 2) displaced between the ceiling plate 48 and bottom plate 50. Further, a plurality of circular ring-shaped fins 54 are installed in the middle of the pillars 52 at predetermined pitches.

Heat from a heating unit, which will be described below, is accumulated in a portion of the heat retention unit 30, to keep the heat in the lower end region of the wafer boat 22 so that the temperature of the region is not excessively lowered. Here, although the heat retention unit 30 and the wafer boat 22 are formed individually from each other, both of them may be integrally formed of quartz. Also, as the heat retention unit 30, a thermos container formed of quartz in the shape of a circular cylinder may also be used.

In addition, a circular cylinder-shaped heating unit 56, which includes a carbon wire heater, is installed to a lateral side and ceiling portion of the processing chamber 4 so as to surround it. Thus, the heating unit 56 is configured to heat the semiconductor wafers W positioned therein. The heating unit 56 is divided into a plurality of heating zones corresponding to the wafer accommodation regions. For example, five heating zones divided by horizontal dotted lines are illustrated in FIG. 1. Thermocouples 58, which are temperature measuring units for the chamber, are respectively installed to the heating zones, and the temperature for each heating zone can be controlled in a feedback manner.

Further, in the processing chamber 4, a gas supply system 60 having a feature of the present disclosure for supplying a gas necessary for the heat treatment is connected and installed to one side of the lower end of the processing chamber 4. The gas supply system 60 has an inert gas channel 62 for allowing an inert gas, such as an N₂ gas, to flow. A flow rate controller 64 such as a mass flow controller and an opening/closing valve 66 are installed in sequence in the inert gas channel 62 from the upstream side thereof toward the downstream side. Further, the most downstream side of the inert gas channel 62 is connected to a gas supply header portion 68, which is provided in the lower end of the processing chamber 4 and has a feature of the present disclosure for allowing the inert gas to flow along the circumferential direction of the lower end. A gas introduction portion 70 for introducing the inert gas into the processing chamber 4 is installed to the gas supply header portion 68.

Specifically, as shown in FIGS. 1 and 3A, the gas supply header portion 68 is configured, for example, by welding and bonding a partition member 72 formed of quartz, for example having a U-shaped cross section, along an outer wall surface 4A of the lower end of the processing chamber 4, wherein a gas passage 74 is defined within the partition member 72. Also, a gas inlet 76 is formed in one end of the partition member 72, and the most downstream side of the inert gas channel 62 is connected to the gas inlet 76, thereby allowing the N₂ gas to flow.

In case of FIG. 3A, the gas passage 74 extends to an about half (semicircle) of the circular cylindrical processing chamber 4, and the gas introduction portion 70 is formed in the middle of the gas passage 74. The number of the gas introduction portion 70 may be one or more. In case of FIG. 3A, the gas introduction portions 70 are installed at a position about 90 degrees and 180 degrees from the gas inlet 76, respectively around the center of the processing chamber 4, i.e., the two gas introduction portions 70 are formed on the whole.

The gas introduction portion 70 includes a gas injection hole 78 that is formed by penetrating a sidewall of the processing chamber 4, and the N₂ gas is allowed to be introduced into the processing chamber 4 through the gas injection hole 78. The gas injection hole 78 is formed facing the heat retention unit 30.

Herewith, when the N₂ gas, which is an inert gas, flows along the inside of the gas passage 74, it is possible to heat the N₂ gas by the high temperature sidewall of the processing chamber 4 partitioning the inside of the gas passage 74. Therefore, in order to heat the N₂ gas introduced into the gas passage 74 at a certain temperature or higher, the gas introduction portion 70 closest to the gas inlet 76 is located at a position 90 degrees or more from the gas inlet 76 around the center of the processing chamber 4, as described above.

Herewith, the heated N₂ gas is allowed to be injected and introduced into the processing chamber 4 from the respective gas injection holes 78. In such a case, in order that the approximately same amount of the N₂ gas is introduced from the respective gas injection holes 78, it is preferred that an opening area of the gas injection hole 78 be gradually enlarged as going toward the downstream side of the gas passage 74. The partition member 72 formed of quartz is not limited to the member having a U-shaped cross section, but may include a quartz tube.

Also, FIG. 3B shows a modification of the gas supply header portion 68. Here, the gas supply header portion 68 is installed to make about one revolution around the processing chamber 4, and four gas introduction portions 70 (four gas injection holes 78) are provided at positions rotated about every 90 degrees around the center of the processing chamber 4, i.e., at positions spaced apart from each other at a predetermined interval. Even in such a case, in order to introduce the approximately same amount of the N₂ gas from the respective gas injection holes 78, it is preferred that an opening area of the gas injection hole 78 is gradually enlarged as going toward the downstream side of the gas passage 74.

Return to FIG. 1, this heat treatment apparatus is provided with an apparatus control unit 80, for example including a microcomputer and the like, in order to control the supply amount of gas, process temperature, process pressure, and the like or control the operation of the entire heat treatment apparatus. The apparatus control unit 80 includes a storage medium 82 for storing programs used when the operation of the heat treatment apparatus 2 is controlled.

The storage medium 82 includes, for example, a flexible disk, a CD (Compact Disc), a hard disk, a flash memory, a DVD, and the like. Also, although not shown, a variety of instructions, programs, and the like may be input into the apparatus control unit 80 through a user interface using a dedicated line.

Next, the heat treatment performed using the heat treatment apparatus 2 of the first embodiment configured as described above will be described. Each operation described below is performed under the control of the apparatus control unit 80 including a computer, as described above.

In a practical treatment, untreated semiconductor wafers W, for example including silicon substrates, are first supported in the wafer boat 22 in a multistage manner. In such a state, the wafer boat 22 is loaded into the processing chamber 4, which is preheated, for example, at 100 degrees C. or so, from the below thereof and accommodated therein in an air-tight state. The semiconductor wafer W has a diameter, for example, of 300 mm, approximately 50 to 150 sheets of the semiconductor wafers W are accommodated. The semiconductor wafer W has had photoresist applied to a surface thereof and has been subjected, for example, to a pre-bake process or the like in a pre-treatment process.

During the heat treatment, the atmosphere in the processing chamber 4 is continually evacuated by the evacuation system 12 such that the pressure therein is adjusted. Also, the semiconductor wafers W rotate at a predetermined rotating speed by rotating the wafer boat 22 during the heat treatment. In addition, the gas supply system 60 allows the N₂ gas, which is an inert gas, to be introduced into the processing chamber 4 from the gas supply header portion 68 at the lower end of the processing chamber 4. At the same time, the power supplied to the heating unit 56 is increased to elevate the temperature of the processing chamber 4 and the wafers W and keep the process temperature, for example, at about 150 to 250 degrees C. At this process temperature, the photoresist on the wafers W is subjected to vitrification. That is, moisture, solvent and the like, which are contained in the photoresist, are evaporated, so that the photoresist becomes hardened. At this time, the process pressure is in a range of 500 torr or so at room temperature.

The moisture, solvent and the like generated at this time are involved in N₂ gas and delivered when the N₂ gas introduced from the gas supply header portion 68 located at the lower end of the processing chamber 4 flows upward in the processing chamber 4 from below. Then, the N₂ gas containing the moisture, solvent and the like reaches the ceiling portion of the processing chamber 4, is discharged from the exhaust chamber 8 to the outside of the processing chamber 4, and then, flows out through the exhaust pipe 10 and the exhaust channel 14 of the evacuation system 12.

Here, in a conventional treatment apparatus, an N₂ gas at about room temperature is introduced into a lower portion of a processing chamber, and cold spots of low temperature are generated in this lower portion. Thus, the evaporated gas containing a photosensitizing agent component of photoresist is condensed to be formed into powdery or liquid deposition, which is in turn attached to a surface, for example, of a thermos container positioned in this lower portion. However, according to the present disclosure, it is possible to prevent the deposition from being generated. That is, the N₂ gas flowing from the inert gas channel 62 of the gas supply system 60 is introduced into the gas passage 74 from the gas inlet 76 of the gas supply header portion 68 installed at the lower end of the processing chamber 4. Then, the N₂ gas flows along the gas passage 74 and is introduced into the processing chamber 4 from the respective gas injection holes 78 of the respective gas introduction portions 70.

Here, the sidewall of the lower end of the processing chamber 4 and the partition member 72 joined to the sidewall to define the gas supply header portion 68. The gas supply header portion 68 is spaced slightly apart from the heating unit 56 but has sufficiently high temperature due to thermal conduction. In addition, thermal capacity of this portion is also increased by as much as that caused by the installation of the partition member 72. Therefore, the N₂ gas flowing along the gas passage 74 becomes heated and has elevated temperature.

In such a case, since the temperature of the N₂ gas is increased as the distance by which the N₂ gas flows along the gas passage 74 is increased, the temperature of the N₂ gas injected from the gas injection hole 78 at the position opposite to (rotated 180 degrees from) the gas inlet 76 is higher than that of the N₂ gas injected from the gas injection hole 78 at the position rotated 90 degrees from the gas inlet 76. Thus, since the N₂ gas injected into the processing chamber 4 from the respective gas injection holes 78 is in a preheated state and its temperature has been elevated to a certain temperature, the generation of cold spots are prevented, thereby making it possible to prevent deposition from being attached to the fins 54 or pillars 52 of the heat retention unit 30 or an inner wall surface of the lower end of the processing chamber 4.

Therefore, it is possible not only to prevent particles caused by the deposition from being generated but also to prolong/extend a period between maintenance such as wet cleaning. Particularly, if it is possible to completely prevent the attachment of the deposition, the maintenance can be all together unnecessary.

Also, since the lid portion 34 of the lower end of the processing chamber 4 has been heated by the lid portion heater 42, it is also possible to prevent deposition from being attached to a surface of the lid portion 34. In such a case, a flow rate of the N₂ gas depends on the capacity of the processing chamber 4 and, for example, is in a range between about 10 and 20 liters/min. Here, in case of the modification shown in FIG. 3B, since the gas introduction portions 70 (the gas injection holes 78) are approximately equal distance apart around the lower end of the processing chamber 4, it is possible to allow the N₂ gas to be approximately uniformly dispersed and flow around a wafer W.

As described above, according to the first embodiment of the present disclosure, since the inert gas (e.g., N₂ gas) to be introduced into the processing chamber 4 has been preheated, it is possible to prevent powdery or liquid deposition from being attached to the lower portion of the processing chamber 4.

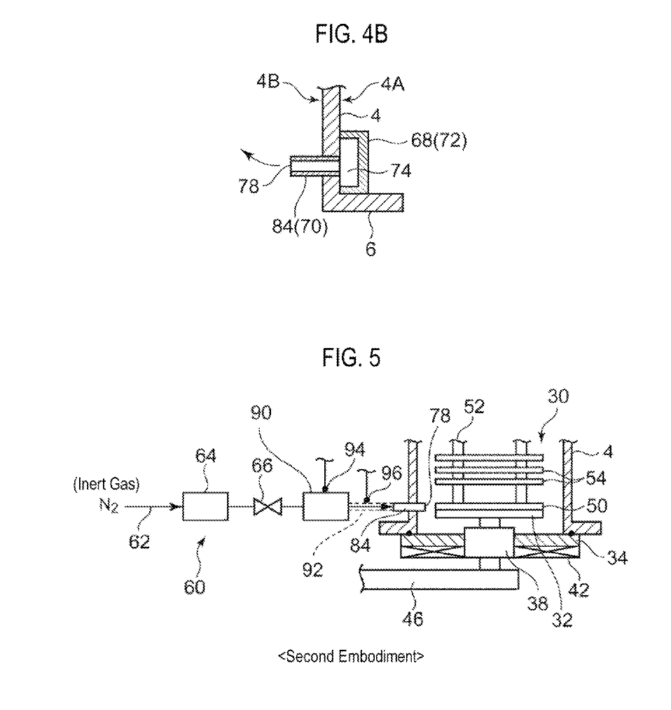

Here, a modification of the gas supply header portion 68 shown in FIGS. 4A and 4B will be described. FIGS. 4A and 4B are a view partially showing a modification of the gas supply header. Also, the same reference numerals are used to designate the same elements as described above. In the embodiment shown in FIGS. 1 to 3A and 3B, the gas supply header portion 68 is defined along the outer wall surface 4A of the lower end of the processing chamber 4, but is not limited thereto. That is, as shown in FIG. 4A, the gas supply header portion 68, i.e., the partition member 72 may be installed to an inner wall surface 4B of the lower end of the processing chamber 4.

Also, in case of the embodiment shown in FIGS. 1 to 3A and 4A, the gas injection hole 78, as the gas introduction portion 70, is configured by forming a through hole in the sidewall of the processing chamber 4, but is not limited thereto. That is, as shown in FIG. 4B, a gas nozzle 84, for example made of quartz, as the gas introduction portion 70, may be formed to penetrate the sidewall of the processing chamber 4. In such a case, the gas injection hole 78 is located at a leading end of the gas nozzle 84.

### Second Embodiment

Next, a second embodiment of the heat treatment apparatus according to the present disclosure will be described. FIG. 5 is a partial view showing the configuration of the second embodiment of the heat treatment apparatus according to the present disclosure. The same reference numerals are used to designate the same elements as the embodiment previously described, and redundant descriptions thereof will be omitted. Although in the previous first embodiment, the gas supply system 60 is provided with the gas supply header portion 68 or the like, an inert gas heating unit for heating an inert gas may be instead installed to the gas supply system 60.

As shown in FIG. 5, an inert gas heating unit 90 is installed in the middle of the inert gas channel 62 of the gas supply system 60 for allowing an inert gas to flow, and is configured so that an N₂ gas, which is the inert gas, can be heated at a predetermined temperature to elevate its temperature. The heating temperature of the N₂ gas is preferably set, for example, to be equal to the process temperature or so. In addition, the most downstream side of the inert gas channel 62 is connected to the gas nozzle 84, penetrating the sidewall of the lower end of the processing chamber 4. The connection enables the N₂ gas to be introduced into the lower portion of the processing chamber 4.

The gas nozzle 84 serves as the gas introduction portion, and is configured so that the gas injection hole 78 of the gas nozzle 84 faces the lower portion of the heat retention unit 30. In addition, a heat retaining heater portion 92, for example including a tape heater or the like, is installed along the inert gas channel 62 between the inert gas heating unit 90 and the processing chamber 4, i.e., the gas nozzle 84, thereby retaining the temperature of the heated N₂ gas flowing in the inert gas channel 62.

As a result, the N₂ gas heated, for example up to around the process temperature, may be introduced into the lower portion of the processing chamber 4. Also, the inert gas heating unit 90 and the heat retaining heater portion 92 are provided with temperature measuring units such as thermocouples 94 and 96, respectively. Then the measured values are sent to the apparatus control unit 80 for the temperature control in a feedback control manner.

In this second embodiment, since the N₂ gas preheated by the inert gas heating unit 90 can be introduced into the lower portion of the processing chamber 4 as described above, the same functional effects as the previous first embodiment can be exhibited.

### Third Embodiment

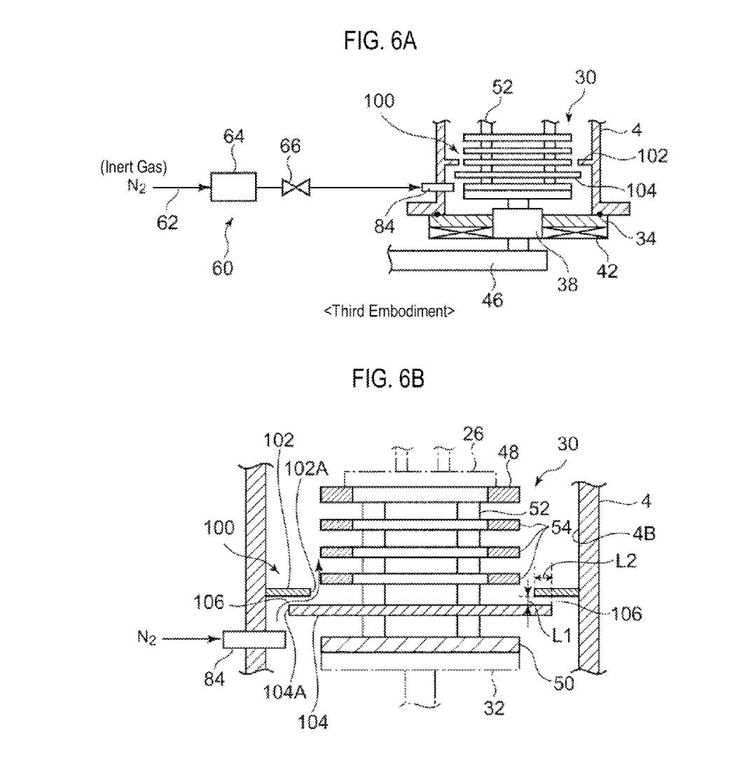

Next, a third embodiment of the heat treatment apparatus according to the present disclosure will be described. FIGS. 6A and 6B is a partial view showing the configuration of the third embodiment of the heat treatment apparatus according to the present disclosure, wherein FIG. 6A shows the configuration of a lower portion of a processing chamber and FIG. 6B shows an enlarged view thereof. The same reference numerals are used to designate the same elements as the embodiments previously described, and redundant descriptions thereof will be omitted. Although in the previous first embodiment, the gas supply system 60 is provided with the gas supply header portion 68 or the like, a winding channel structure for heating an inert gas may be instead provided.

That is, as shown in FIGS. 6A and 6B, in the third embodiment, a winding channel structure 100, which defines a winding channel configured to hinder the flow of an N₂ gas, which is an inert gas, flowing upward within the processing chamber 4 and to heat the N₂ gas, is installed within the processing chamber 4, between the lower end of the processing chamber 4 and the heat retention unit 30. The gas supply system 60 of this embodiment is equivalent to the gas supply system 60 of the second embodiment shown in FIG. 5 with the inert gas heating unit 90, the heat retaining heater portion 92, or the like removed. The leading end of the gas supply system 60 is the gas nozzle 84, which is the gas introduction portion. The winding channel structure 100 is positioned above the gas nozzle 84.

The winding channel structure 100 includes a ring-shaped outside hindrance plate 102 installed to the inner wall surface 4B of the processing chamber 4 and an inside hindrance plate 104 installed to the heat retention unit 30 and formed to have a leading end radially outward extending from an inner peripheral end 102A of the outside hindrance plate 102. An outer peripheral end 104A of the inside hindrance plate 104 is positioned more outward than the inner peripheral end 102A of the outside hindrance plate 102 in the radial direction of the processing chamber 4.

In other words, the ring-shaped outside hindrance plate 102 is configured to have an inner diameter smaller than an outer diameter of the inside hindrance plate 104. In addition, the outside hindrance plate 102 is configured to have an inner diameter larger than an outer diameter of the fins 54. Thus, they do not interfere with each other when the wafer boat 22 goes up and down.

Here, the inside hindrance plate 104 is formed in the shape of a circular disk and fixed to the pillars 52 of the heat retention unit 30. Further, the inside hindrance plate 104 is arranged to approach a portion directly below the outside hindrance plate 102, whereby a winding channel 106 is formed to be successively bent 90 degrees between the outer peripheral portion of the inside hindrance plate 104 and the inner peripheral portion of the outside hindrance plate 102. The winding channel 106 is a passage bent 90 degrees from an upward direction to a horizontal direction and in turn 90 degrees to an upward direction along the gas flow, which has a crank or labyrinth shape on the whole, thereby being capable of heating the N₂ gas passing through the winding channel 106.

The winding channel 106 is continuously formed along the circumference of the processing chamber 4. Here, the outside hindrance plate 102 and the inside hindrance plate 104 are formed, for example, of quartz. A distance L1 between the hindrance plates 102 and 104 is about 5 to 7 mm, and an overlapping length L2 between the hindrance plates 102 and 104 is about 4 to 10 mm. Here, the inside hindrance plate 104 is installed below the fin 54 at the lowest position of the plurality of fins 54, and also, the gas nozzle 84 is located below the hindrance plate 104.

In the third embodiment, since the winding channel structure 100 having the outside hindrance plate 102 and the inside hindrance plate 104 is installed between the lower end of the processing chamber 4 and the heat retention unit 30, both hindrance plates 102 and 104 are at sufficiently high temperature due to thermal conduction. In addition, thermal capacity of this portion is increased by as much as that caused by the installation of both hindrance plates 102 and 104. Therefore, the N₂ gas receives heat from both the hindrance plates 102 and 104 to be heated and elevate its temperature when the N₂ gas flows in the winding channel 106 defined by them.

Therefore, even in such a case, the same functional effects as the previous first embodiment can be exhibited. That is, since the inert gas introduced into the processing chamber 4 can be heated arranged, it is possible to prevent powdery or liquid deposition from being attached to the lower portion of the processing chamber 4.

### Fourth Embodiment

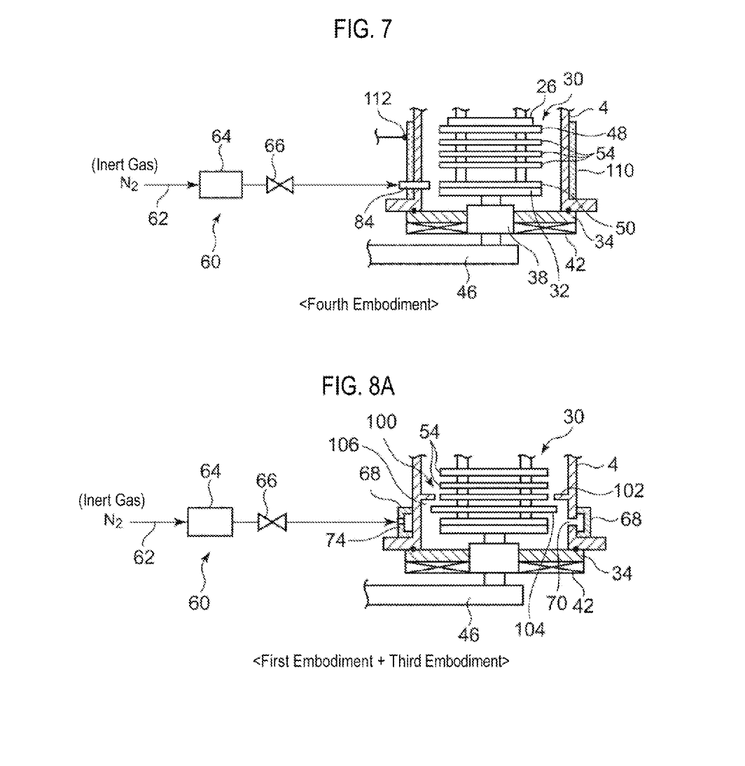

Next, a fourth embodiment of the heat treatment apparatus according to the present disclosure will be described. FIG. 7 is a partial view showing the configuration of the fourth embodiment of the heat treatment apparatus according to the present disclosure. The same reference numerals are used to designate the same elements as the respective embodiments previously described, and redundant descriptions thereof will be omitted. Although in the previous first embodiment, the gas supply system 60 is provided with the gas supply header portion 68 or the like, a lower chamber heating unit may be instead installed to the lower end of the processing chamber 4.

As shown in FIG. 7 of the fourth embodiment, in order to heat the inert gas introduced into the processing chamber 4, a lower chamber heating unit 110 is installed to the lower end of the processing chamber 4 along the circumference thereof, thereby heating the N₂ gas, which is the inert gas introduced into the processing chamber 4. In FIG. 7, the gas supply system having the gas nozzle 84 as shown in FIGS. 6A and 6B is used as the gas supply system 60. The lower chamber heating unit 110 includes, for example, a resistance heater and is installed along the outer peripheral surface of the processing chamber 4. The lower chamber heating unit 110 is in the shape of a band for covering the approximately entire height of the heat retention unit 30, corresponding to a lateral side of the heat retention unit 30.

In addition, the lower chamber heating unit 110 is provided with a temperature measuring unit, such as a thermocouple 112, wherein the measured value is sent to the apparatus control unit 80 to perform the temperature control in a feedback control manner. The temperature of the lower chamber heating unit 110 is set to be approximately equal, for example, to the process temperature.

In the fourth embodiment, since the lower end of the processing chamber 4 and the heat retention unit 30 positioned therein are heated even by the lower chamber heating unit 110 installed in this embodiment as well as the conventional heating unit 56 (see FIG. 1), the N₂ gas can be heated up to high enough temperature when the N₂ gas introduced from the gas nozzle 84 rises in the lower portion of the processing chamber 4. Therefore, even in such a case, the same functional effects as the previous first embodiment can be exhibited. That is, since the inert gas introduced into the processing chamber 4 can be immediately heated, it is possible to prevent powdery or liquid deposition from being attached to the lower portion of the processing chamber 4.

### Combination of Respective Embodiments

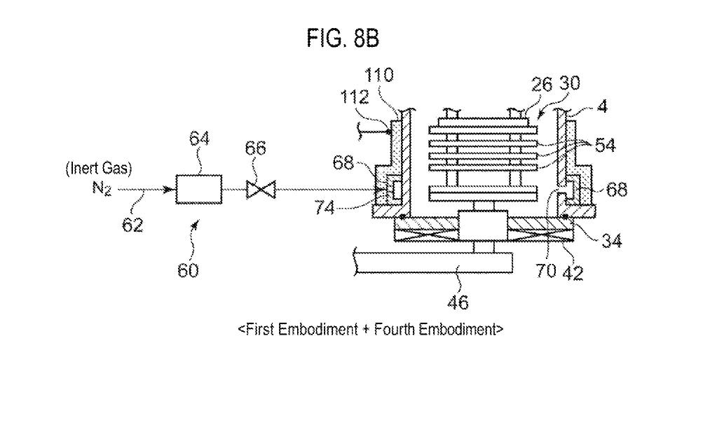

As described above, although the first to fourth embodiments have been described until now, any two or more of the first to fourth embodiments (including the modifications) may be combined. FIGS. 8A and 8B are partial views showing examples of the heat treatment apparatus in which the respective embodiments are combined as described above. FIG. 8A shows a combination of the first and third embodiments, and FIG. 8B shows a combination of the first and fourth embodiments. The same reference numerals are used to designate the same elements as the respective embodiments previously described, and redundant descriptions thereof will be omitted.

In the case shown in FIG. 8A, as described above, the gas supply system 60 of the first embodiment and the winding channel structure 100 of the third embodiment are installed. The gas supply system 60 has the gas supply header portion 68 and the gas introduction portion 70. Also, in the case shown in FIG. 8B, as described above, the gas supply system 60 of the first embodiment and the lower chamber heating unit 110 of the fourth embodiment are installed, and the gas supply system 60 has the gas supply header portion 68 and the gas introduction portion 70.

In the respective embodiments shown in FIGS. 8A and 8B, synergy effects of a plurality of embodiments can be exhibited. That is, since the inert gas to be introduced into the processing chamber 4 is preheated and also the inert gas introduced into the processing chamber 4 is more heated, it is possible to prevent powdery or liquid deposition from being attached to the lower portion of the processing chamber 4.

In addition, although an N₂ gas is used as an inert gas in the embodiments described above, the present disclosure is not limited thereto, and a noble gas, such as Ar or He, may be used. Also, although a semiconductor wafer, as an object to be treated, is described as an example, the semiconductor wafer also includes a silicon substrate or a compound semiconductor substrate, such as GaAs, SiC, or GaN. In addition, the present disclosure is not limited to these substrates and may be applied to a glass substrate used in a liquid crystal display, a ceramic substrate, or the like.

According to the present disclosure, since the inert gas to be introduced into the processing chamber is preheated, it is possible to prevent powdery or liquid deposition from being attached to the lower portion of the processing chamber.

Further, according to the present disclosure, the inert gas introduced into the processing chamber can be immediately heated, it is possible to prevent powdery or liquid deposition from being attached to the lower portion of the processing chamber.

Furthermore, according to the present disclosure, since the inert gas to be introduced into the processing chamber is preheated and the inert gas introduced into the processing chamber is more heated, it is possible to prevent powdery or liquid deposition from being attached to the lower portion of the processing chamber.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a gas supply system configured to supply the inert gas,
wherein the gas supply system comprises:
a gas supply header portion located in a lower end of the processing chamber to allow the inert gas to flow along a circumferential direction of the lower end; and
a gas introduction portion in communication with the gas supply header portion to introduce the inert gas into the processing chamber.

2. The apparatus of claim 1, wherein the gas introduction portion comprises a plurality of gas introduction portions spaced apart from each other along the gas supply header portion at a predetermined interval.

3. The apparatus of claim 1, wherein the gas supply header portion is located along an outer wall surface of the processing chamber.

4. The apparatus of claim 1, wherein the gas supply header portion is located along an inner wall surface of the processing chamber.

5. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a gas supply system configured to supply the inert gas, wherein the gas supply system comprises an inert gas heating unit installed to an inert gas channel to heat the inert gas, wherein the inert gas channel allows the inert gas to flow.

6. The apparatus of claim 5, wherein the inert gas channel positioned between the inert gas heating unit and the processing chamber is provided with a heat retaining heater portion along the inert gas channel.

7. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a heat retention unit configured to retain temperature of a lower end of the holding and supporting unit; and
a winding channel structure positioned between a lower end of the processing chamber and the heat retention unit, thereby defining a winding channel configured to hinder the flow of the inert gas flowing upward the top and to heat the inert gas.

8. The apparatus of claim 7, wherein the winding channel structure comprises a ring-shaped outside hindrance plate installed to an inner wall surface of the lower end of the processing chamber, and an inside hindrance plate installed to the heat retention unit and formed to have a leading end extending more radially outward than an inner peripheral end of the outside hindrance plate.

9. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a lower chamber heating unit installed to a lower end of the processing chamber along a circumferential direction thereof to heat the inert gas introduced into the processing chamber.

10. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a gas supply system configured to supply the inert gas,
wherein the gas supply system comprises:
a gas supply header portion located in a lower end of the processing chamber to allow the inert gas to flow along a circumferential direction of the lower end; and
a gas introduction portion in communication with the gas supply header portion to introduce the inert gas into the processing chamber;
a heat retention unit configured to retain temperature of a lower end of the holding and supporting unit; and
a winding channel structure positioned between a lower end of the processing chamber and the heat retention unit, thereby defining a winding channel configured to hinder the flow of the inert gas flowing upward the top and to heat the inert gas.

11. The apparatus of claim 10, wherein the gas introduction portion comprises a plurality of gas introduction portions spaced apart from each other along the gas supply header portion at a predetermined interval.

12. The apparatus of claim 10, wherein the gas supply header portion is located along an outer wall surface of the processing chamber.

13. The apparatus of claim 10, wherein the gas supply header portion is located along an inner wall surface of the processing chamber.

14. The apparatus of claim 10, wherein the winding channel structure comprises a ring-shaped outside hindrance plate located to an inner wall surface of the lower end of the processing chamber and an inside hindrance plate located to the heat retention unit and formed to have a leading end extending more radially outward than an inner peripheral end of the outside hindrance plate.

15. A heat treatment apparatus configured to heat treat a plurality of objects to be treated which are held and supported by a holding and supporting unit while an inert gas is allowed to flow in a vertical type processing chamber from a bottom to a top thereof, wherein the processing chamber has a heating unit installed therearound, the apparatus comprising:
a gas supply system configured to supply the inert gas,
wherein the gas supply system comprises:
a gas supply header portion located in a lower end of the processing chamber to allow the inert gas to flow along a circumferential direction of the lower end;
a gas introduction portion in communication with the gas supply header portion to introduce the inert gas into the processing chamber; and
a lower chamber heating unit located in the lower end of the processing chamber to heat the inert gas introduced into the processing chamber along the circumferential direction of the lower end.

16. The apparatus of claim 15, wherein the gas introduction portion comprises a plurality of gas introduction portions spaced apart from each other along the gas supply header portion at a predetermined interval.

17. The apparatus of claim 15, wherein the gas supply header portion is located along an outer wall surface of the processing chamber.

18. The apparatus of claim 15, wherein the gas supply header portion is located along an inner wall surface of the processing chamber.

19. The apparatus of claim 1, wherein the heat treatment is a vitrification treatment for vitrifying photoresist formed on a surface of the object to be treatment.
